(19) United States
(12) Patent Application Publication
(10) Pub. No.: US 2023/0170193 A1
(43) Pub. Date: Jun. 1, 2023

(54) METHOD, APPARATUS, SERVER AND COMPUTER-READABLE STORAGE MEDIUM FOR MONITORING PARTICLES IN AN ETCHING CHAMBER

(71) Applicant: HANGZHOU FULLSEMI SEMICONDUCTOR CO., LTD., Hangzhou (CN)

(72) Inventor: Zhiqin Shen, Hangzhou (CN)

(21) Appl. No.: 17/966,739

(22) Filed: Oct. 14, 2022

(30) Foreign Application Priority Data
Dec. 1, 2021 (CN) 202111451988.X

(51) Int. Cl. H01J 37/32

(52) U.S. Cl. CPC H01J 37/32963; H01J 37/32862; H01J 2237/334

(57) ABSTRACT

A method, device, server and computer-readable storage medium for monitoring particles in an etching chamber are provided. When performing a WAC process in the etching machine, an EPD data curve of spectral signal intensity varying with time in the etching machine can be obtained through an OES EPD module, the EPD data differential curve can be obtained through differentiation calculation performed on the EPD data curve, and a particle-drop determination can be performed on the etching chamber by acquiring and analyzing the peak value signal of the EPD data differential curve. The OES EPD module directly monitors particle dropping during the WAC process in the etching chamber, so as to facilitate subsequent processes. The present disclosure reduces labor cost, improves determination accuracy, and avoids contamination of the etching chamber and process wafers caused by particle droppings, thereby improving monitoring efficiency, reducing losses, and reducing negative impact on wafer quality.

### FIELD OF INVENTION

The present disclosure relates to the field of semiconductor manufacturing, in particular to a method, a device, a server and a computer-readable storage medium for monitoring particles in an etching chamber.

### BACKGROUND

In semiconductor etching processes, when process plasma reacts with a wafer in an etching chamber, reaction residues can be generated on inner walls of the etching chamber and some surfaces of any hardware components, creating defects on the wafer. affecting the process quality. Usually, to clean the post process chamber after the wafer is taken out of the etching chamber, a cleaning gas is introduced into the etching chamber, a high voltage generated plasma ionizes the cleaning gas, and performs the waferless auto clean (WAC) process on the etching chamber, so that plasma cleans the inner walls of the etching chamber as well as the surfaces of other components exposed to the plasma. The WAC process cleans the etching chamber after the etching process of a previous wafer is completed, before a next wafer is introduced for subsequent etching. By repeating the above step, a scaled-up wafer etching process can be achieved. WAC serves to reduce the residues in the etching chamber, so as to mitigate the chamber memory effect due to the residues, and reduce the wafer defect rate.

With the development of integrated circuit technology, the required accuracy of wafer processing in an etching chamber is getting higher, and the requirements on the environment of the etching chamber are becoming more demanding. As a high-precision device, a chip is easily contaminated during its production process. Controlling and reducing contamination will effectively improve chip yield and increase profits. However, in the WAC process, residues attached to the etching chamber are likely to become unstable, and may fall off during the WAC process, causing secondary contamination to the etching chamber and affecting subsequent processes.

Therefore, it is necessary to provide a method, a device, a server and a computer-readable storage medium for monitoring particles in an etching chamber.

### SUMMARY

The present disclosure provides a method for monitoring particles in an etching chamber, comprising providing an etching machine equipped with an optical emission spectrograph (OES) endpoint-detection (EPD) module; performing a Waferless Auto Clean (WAC) process on the etching machine, and obtaining an EPD data curve showing spectral signal intensity varying with time in the etching chamber via the OES EPD module; performing differentiation calculation on the EPD data curve, to obtain an EPD data differential curve; and obtaining and analyzing a peak value signal of the EPD data differential curve, to perform a particle-drop determination.

In an embodiment, the particle-drop determination comprises: acquiring a particle dropping baseline data point by performing the differentiation calculation on an EPD data curve of a baseline particle dropping; setting a threshold for the EPD data differential curve according to the spectral signal intensity of the particle dropping baseline data point; and when the peak value signal exceeds the threshold within a preset period, determining that there is a particle dropping.

In an embodiment, the preset period lasts for 3 to 5 seconds.

In an embodiment, the step of obtaining a peak value signal of the EPD data differential curve comprises: obtaining a data signal range within which a slope of the EPD data differential curve is first negative and then positive, or vice versa.

In an embodiment, the method further comprises performing a primary or secondary differentiation calculation on the EPD data differential curve to obtain a second-order derivative of the EPD data curve and a third-order derivative of the EPD data curve, respectively

In an embodiment, the method further comprises activating an alarm component when it is determined the etching machine has particle dropping occurred within.

In an embodiment, the alarm component comprises one of a sound alarm, light alarm, and sound-light alarm.

The present disclosure further provides an apparatus for monitoring particles in an etching chamber, comprising: a WAC module configured to perform a WAC process on the etching chamber; an OES EPD module configured to generate an EPD data curve showing spectral signal intensity varying with time in the etching chamber; a data processing module configured to perform differentiation on the EPD data curve, and obtain an EPD data differential curve; and a selection determination module configured to obtain a peak value signal of the EPD data differential curve, and analyze the peak value signal, in order to perform particle-drop determination.

The present disclosure further provides a server comprising a collector, a memory and a processor, wherein the collector is configured to collect data for plotting an EPD data curve; the collector, the memory, and the processor are communicably connected with one another; the memory stores computer commands; and the processor executes the computer commands to perform the method for monitoring particles in the etching chamber.

The present disclosure further provides a non-transitory computer-readable storage medium storing computer commands to be executed by a computer to perform the method for monitoring particles in the etching chamber.

### BRIEF DESCRIPTION OF THE DRAWINGS

FIG. 1 is a flowchart illustrating a method of monitoring contamination particles in an etching chamber according to an embodiment of the present disclosure.

FIG. 2 is a data chart illustrating an exemplary EPD data curve showing spectral signal intensity varying with time according to an embodiment of the present disclosure.

FIG. 3 is a data chart showing the EPD data differential curve after performing a primary differentiation calculation on the exemplary EPD data curve of FIG. 2 according to an embodiment of the present disclosure.

FIG. 4 is a data chart illustrating the EPD data differential curve after performing a secondary differentiation calculation on the exemplary EPD data curve of FIG. 2 according to an embodiment of the present disclosure.

FIG. 5 is a block diagram illustrating a schematic structure of an apparatus for monitoring particles in an etching chamber according to an embodiment of the present disclosure.

FIG. 6 a block diagram illustrating structural connections between various modules in a server according to an embodiment of the present disclosure.

### DETAILED DESCRIPTION

The following specific examples illustrate the embodiments of the present invention, and those skilled in the art can easily understand other advantages and efficacy of the present invention from the disclosure of this specification. The invention can also be implemented or applied by other different embodiments, and the details in this specification can be modified or changed based on different viewpoints and applications without departing from the spirit of the invention.

Furthermore, the described features, structures or characteristics may be combined in any appropriate way in one or more embodiments. In the following description, many specific details are provided for better understanding of the embodiments of the present invention. However, those skilled in the art will realize that the technical scheme of the present invention can be practiced without one or more specific details, and may adopt other methods, components, devices, steps, etc. In order to focus on the inventive points of the present disclosure, some known methods, devices, implementations or operations are not shown in details.

The block diagrams merely show functional entities and not necessarily correspond to their physical counterparts. That is, these functional entities can be implemented in the form of software, or in one or more hardware modules or integrated circuits, or in different networks and/or processing devices and/or microcontroller devices.

The flowchart shown in the drawings is merely an exemplary illustration, and does not necessarily reveal all the possible operations/steps, nor the exact order of these operations/steps. For example, some operations/steps can be divided, while some operations/steps can be combined or partially combined, and therefore the actual execution order may change according to the actual situation.

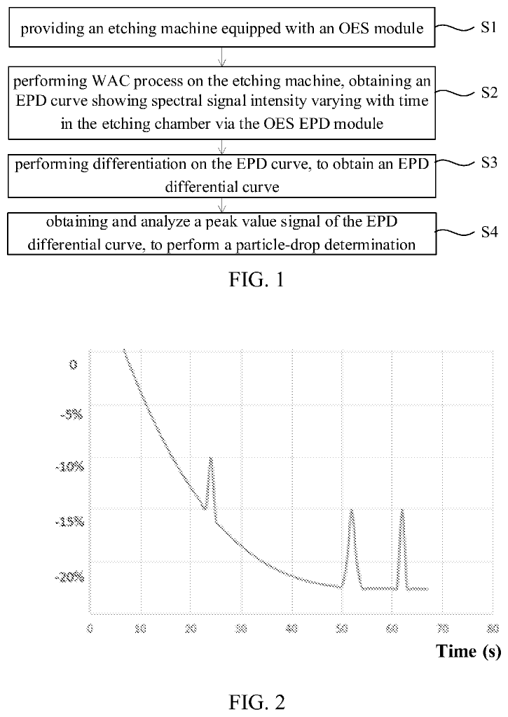

FIG. 1 shows a method for monitoring contamination particles in an etching chamber, which comprises the following steps:

Step S1: provide an etching machine equipped with an optical emission spectrograph (OES) endpoint-detection (EPD) module;

Step S2: perform a Waferless Auto Clean (WAC) process on the etching machine, and obtain an EPD data curve showing spectral signal intensity varying with time through the OES EPD module from the etching chamber;

Step S3: perform differentiation calculation on the EPD data curve to obtain an EPD data differential curve;

Step S4: obtain a peak value signal of the EPD data differential curve and perform analysis on the peak value signal, to perform a particle-drop determination.

In an embodiment, with the aid of the OES EPD module in the etching machine, when performing the WAC process on the etching machine, the OES EPD module can be used to obtain the EPD data curve showing the spectral signal intensity varying with time in the etching chamber, and the EPD data differential curve can be obtained through performing differentiation calculation on the EPD data curve. Herein, the spectral signal intensity refers to the intensity of the optical emission spectrograph obtained from the etching chamber. After the peak value signal of the EPD data curve is analyzed, the particle-drop determination of the etching chamber can be carried out. The OES EPD module directly monitors whether there are particles dropping in the etching chamber during the WAC process, so as to facilitate subsequent processing operations, reduce labor cost, improve the accuracy of determination, and avoid contamination of the etching chamber and wafers due to particle dropping. Hence, the method can improve the monitoring efficiency, reduce manufacturing losses, and reduce impact of particle dropping on wafer quality.

The method of monitoring of the etching chamber particles is further explained in details as follows.

First, Step S1 is facilitated to provide the etching machine equipped with the OES EPD module.

Specifically, the etching machine is provided with a WAC module. The WAC module is configured to perform the WAC process on the etching chamber, so as to use plasma generated by processing gas to etch and clean inner walls of the chamber and surfaces of other components exposed in the plasma. The purpose is to reduce residues in the etching chamber, so as to reduce the chamber memory effect caused by the residues generated by wafer etching, so as to reduce the wafer defect rate.

The etching machine also has a OES EPD module, which is used to detect the completion status of the etching of thin films through an endpoint detection method. The extent to which the plasma etches substances can be determined via plotting an optical emission spectrograph of the substances generated due to chemical changes during plasma etching.

Therefore, during the WAC process, the OES EPD module of the etching machine can obtain the EPD data curve showing spectral signal intensity varying with time in the etching chamber, to analyze particle droppings in the etching chamber.

Next, Step S2 is executed to perform the WAC process on the etching machine, and obtain the EPD data curve showing spectral signal intensity varying with time in the etching chamber through the OES EPD module.

Specifically, with the aid of the OES EPD module, the EPD data curve showing spectral signal intensity varying with time in the etching chamber can be obtained during the WAC process. FIG. 2, shows particle dropping in different stages of the WAC process in one embodiment. The curve fluctuates every time particles drop in the etching chamber, forming a detectable wave peak resulted from enhanced particle signals. After the dropped particles are etched away, the curve will turn stable again. Therefore, particle dropping can be detected via analyzing wave peaks of the EPD data curve.

Next, Step S3 is executed to perform differentiation calculation on the EPD data curve, to obtain the EPD data differential curve.

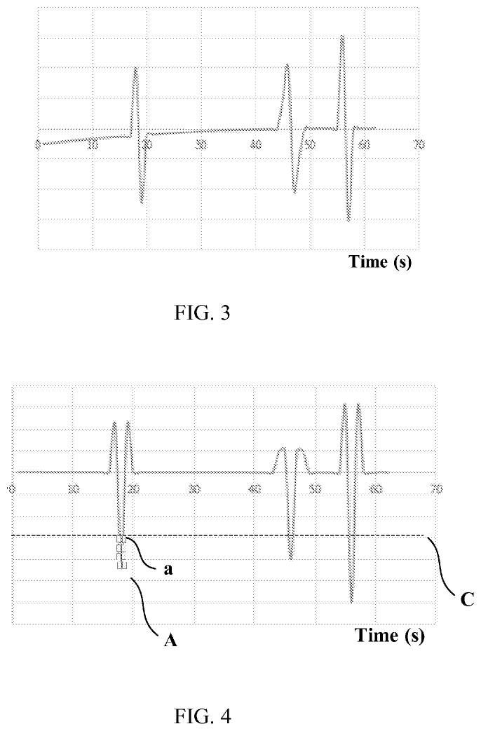

Specifically, by perform differentiation calculation on the EPD data curve, some unwanted peaks are filtered out, and the filtering standard may be set according to the process requirements. Certain low level of particle droppings is allowed depending on the process requirements, and a smoother EPD data differential curve can be obtained via performing differential processing on the EPD data curve, in order to improve the monitoring accuracy. FIG. 3 shows that in one embodiment, after performing a primary differentiation calculation on the EPD data curve, the EPD data differential curve corresponding to the EPD data curve of spectral signal intensity varying with time can be obtained.

Further, according to the process requirements, the method may further include performing a secondary differentiation on the EPD data differential curve after the first differentiation calculation to obtain the curve shown in FIG. 4., That is, the EPD data differential curve shown in FIG. 3 is differentiated again to generate a smoother EPD data differential curve shown in FIG. 4, where the peak value signal A is more prominent. The number of times the EPD data curve should be differentiated can be set according to the actual needs; for example, one time or two times. The differentiation calculation may be carried outonline.

Next, Step S4 is executed to obtain and analyze the peak value signal on the EPD data differential curve to perform particle-drop determination.

For example, Step S4 may include:

acquiring a particle dropping baseline data point by performing the differentiation calculation on an EPD data curve of a baseline particle dropping;

setting a threshold for the EPD data differential curve according to previously recorded changes of spectral signal intensity when particle dropping actually happened; and

determining that there is particle dropping when the peak value signal exceeds the threshold within a certain continuous period.

Specifically, as shown in FIG. 4, the dotted line represents the second-order derivative of the spectral signal intensity according to observations of actual particle dropping, and the threshold level is set as C. The exact value of the threshold level C depends on the state of particles, the etching rate and the processing specification. If the peak value signal A exceeds the threshold C within a certain continuous period, it can be determined that there is particle dropping.

Further, the continuous period can last for 3-5 seconds. For example, the continuous period lasts for 3 seconds, 4 seconds, or 5 seconds, etc. If the peak value signal A exceeds the threshold C, it can be determined that particle dropping occurred. In this way, the accuracy of detecting particle dropping can be improved.

For example, the method of obtaining the peak value signal A of the EPD data differential curve may include: obtaining a continuous signal range within which the slope of the EPD differential is first negative and then positive, or vice versa.

Specifically, as shown in FIG. 4, eight discrete samples a are taken from the curve, their durations are equal, and slopes of the curve are approximated based on the eight samples. If the slopes (that is, the second-order derivatives of the spectrum) change from negative to positive, or vice versa, then a peak value signal falls within the range of the 8 sequential samples, and this peak value signal is referred to as the peak value signal A. Next, if any part of the peak value signal A exceeds the threshold C, it can be determined that particle dropping occurred.

Further, the method may further comprise activating an alarm component when the etching machine is determined to have particle dropping occurred within. The alarm component may adopt one of the following alarm mechanisms: sound alarm, light alarm and sound-light alarm.

Specifically, when the etching machine is determined to have particle dropping occurred within, and the alarm component of the etching machine is activated, the staff can be reminded to take care of issues in time, which improve the overall efficiency.

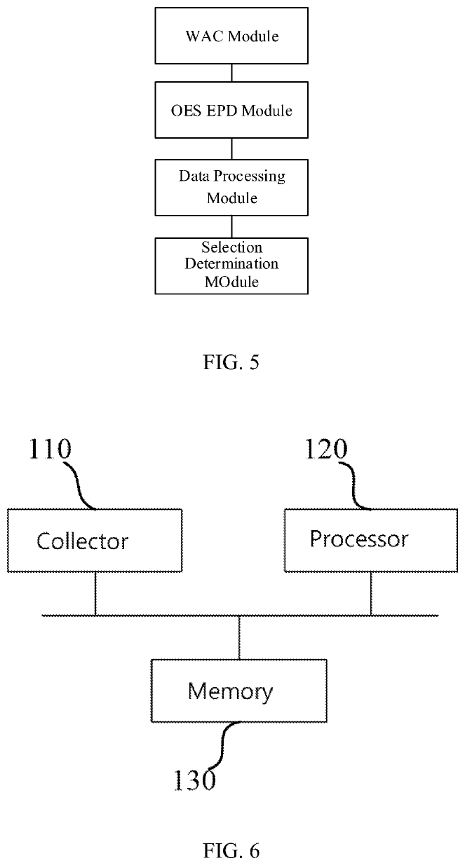

As shown in FIG. 5, the present disclosure further provides an apparatus for monitoring particles in an etching chamber. The apparatus comprises a WAC module, an OES EPD module, a data processing module, and a selection determination module. The WAC module is configured to perform a WAC process on the etching chamber. The OES EPD module is configured to provide an EPD data curve showing spectral signal intensity varying with time in the etching chamber. The data processing module is configured to perform differentiation calculation on the EPD data curve, and then obtain EPD data differential curves. The selection determination module is configured to obtain a peak value signal of the EPD data differential curve, and analyze the peak value signal, in order to perform particle-drop determination.

It should be noted that the above division of modules of the apparatus is only based on logical functions. In actual implementation, these modules may be fully or partially integrated into a physical entity, or separated from one another. In addition, these modules can all be implemented with software to be executed by processing elements. For example, these modules may be implemented with hardware. In another example, some of these modules may be implemented with software, and the rest of these modules may be implemented with hardware. Moreover, all or part of these modules can be integrated, or implemented independently. The aforementioned processing elements may be an integrated circuit with signal processing capability. The steps of monitoring the particles in the etching chamber or each of the above modules can be done in the form of hardware or software (e.g., commands) in the processing element.

For example, the above modules can be one or more integrated circuits configured to monitor the method of the etching chamber particles, such as: one or more application specific integrated circuits (ASIC), digital signal processors (DSP), or field programmable gate arrays (FPGA), etc. In another example, when one of the above modules is implemented in the form of commands to be executed by a process element, the process element may be a general-purpose processor, such as a central processing unit (CPU) or other processors that can execute program codes; these modules may also be integrated to form a system-on-chip (SOC).

The present disclosure also provides a server that comprises: a collector 110, a memory 130 and a processor 120. The collector 110 is configured to collect data for plotting the EPD data curve. The collector 110, the memory 130 and the processor 120 are communicably connected with one another. The memory 130 stores computer commands, and the processor 120 executes the computer commands to perform the aforementioned method for monitoring particles in an etching chamber.

Specifically, the processor 120 and the memory 130 may be connected by a bus wire or in other manners. FIG. 6 shows an example, where the two are connected by a bus wire. The processor 120 can be one or more integrated circuits, such as ASIC, DSP, FPGA, or other processors that can execute codes, such as CPU, or a combination of integrated circuits and processors. The memory 130 is as a non-transitory computer-readable storage medium, and is used to store non-transitory software programs, non-transitory computer executable programs and modules. The processor 120 implements the method of monitoring particles in an etching chamber by running the non-transitory software program, the non-transitory computer executable program and the module stored in the memory 130. The memory 130 may comprises a program storage area and a data storage area. The storage program area may store an application program required by at least one module. The data storage area may store data and the like created by the processor 120. In some embodiments, the memory 130 may comprise one or more remote memory located remotely relative to the processor 120. These remote memories may be connected to the processor 120 through a network that comprises but is not limited to the Internet, Intranet, local area network, mobile communication network, and various combinations thereof. One or more of the above modules may be stored in the memory 130, and to be executed by the processor 120 to perform the method of monitoring the particles in the etching chamber as shown in FIGS. 1-4. As implementation details cab be realized after referring to the related description and effects, they are omitted here for brevity.

The present disclosure also provides a computer-readable storage medium storing computer commands. The computer commands are to be executed by a computer, to perform the method for monitoring particles in an etching chamber described above.

Specifically, those skilled in the art can understand that all or part of the process in the above-mentioned method for monitoring the particles in the etching chamber can be completed by a computer program, and the computer program can be stored in a computer-readable storage medium. The computer program may be executed in the manner of the methods described in the above embodiments. The computer-readable storage medium may be a disk, CD/DVD ROM, read-only memory (ROM), random access memory (RAM), flash memory, hard disk drive (HDD) or solid-state drive (SSD), etc. The computer-readable storage medium may also comprise various combinations of the above types of memories.

In summary, when performing the WAC process on the etching machine, the EPD data curve showing spectral signal intensity varying with time in the etching machine can be obtained through the OES EPD module, the EPD data differential curves can be obtained through differential processing, and the particle-drop determination can be performed on the etching chamber by acquiring and analyzing the peak value signal of the EPD data differential curves. The present disclosure can directly detect any particle dropping that occurs during the WAC process in the etching chamber through the OES EPD module, so as to facilitate subsequent processes. As a result, the present disclosure can reduce labor cost, improve determination accuracy, and avoid contamination of the etching chamber and wafers due to particle dropping, thereby improving monitoring efficiency, reducing losses, and reducing the impact on wafer quality.

The above-mentioned embodiments merely illustrate the principles and effects of the present disclosure, but are not meant to limit the scope of the present disclosure. Any skilled in the art may modify or change the above embodiments without departing from the spirit and scope of the present disclosure. Therefore, all equivalent modifications or changes made by those skilled in the art without departing from the spirit and technical ideas disclosed in the present disclosure shall fall in the claimed scope of the present disclosure.

What is claimed is:

1. A method for monitoring particles in an etching chamber, comprising:
providing an etching machine equipped with an optical emission spectrograph (OES) endpoint-detection (EPD) module;
performing a Waferless Auto Clean (WAC) process on the etching machine after a process on a wafer is completed and the wafer is removed, and obtaining an EPD data curve showing a spectral signal intensity varying with time from via the OES EPD module in the etching chamber;
performing a differentiation calculation on the EPD data curve, to obtain an EPD data differential curve;
obtaining and analyze a peak value signal of the EPD data differential curve; and
performing a particle-drop determination.

2. The method for monitoring particles in the etching chamber according to claim 1, wherein performing the particle-drop determination comprises:
acquiring a particle dropping baseline data point by performing the differentiation calculation on an EPD data curve of a baseline particle dropping;
setting a threshold for the EPD data differential curve according to the spectral signal intensity of the particle dropping baseline data point; and
when the peak value signal exceeds the threshold within a preset period, determining that there is particle dropping.

3. The method for monitoring particles in the etching chamber according to claim 2, wherein the preset period lasts for 3 to 5 seconds.

4. The method for monitoring particles in the etching chamber according to claim 1, wherein the step of obtaining a peak value signal of the EPD data differential curve comprises:
obtaining a data signal range within which a slope of the EPD data differential curve is first negative and then positive, or vice versa.

5. The method for monitoring particles in the etching chamber according to claim 1, further comprising:
performing a primary or secondary differentiation calculation on the EPD data differential curve to obtain a second-order derivative of the EPD data curve and a third-order derivative of the EPD data curve, respectively.

6. The method for monitoring particles in the etching chamber according to claim 1, further comprising activating an alarm component when the etching machine is determined to have particle dropping occurred within.

7. The method for monitoring particles in the etching chamber according to claim 6, wherein the alarm component comprises one of a sound alarm, light alarm, and sound-light alarm.

8. An apparatus for monitoring particles in an etching chamber, comprising:
a WAC module configured to perform a WAC process on the etching chamber;
an OES EPD module configured to generate an EPD data curve showing spectral signal intensity varying with time in the etching chamber;
a data processing module configured to perform differentiation calculation on the EPD data curve, and obtain an EPD data differential curve; and
a selection determination module configured to obtain a peak value signal of the EPD data differential curve, and analyze the peak value signal, in order to perform particle-drop determination.

9. A server, comprising a collector, a memory and a processor, wherein the collector is configured to collect data for plotting the EPD data curve; wherein the collector, the memory, and the processor are communicably connected with one another for communication; wherein the memory stores computer commands; and wherein the processor executes the computer commands to perform the method for monitoring particles in the etching chamber according to claim 1.

10. A non-transitory computer-readable storage medium storing computer commands to be executed by the computer to perform the method for monitoring particles in the etching chamber according to claim 1.
